(19) United States
(12) Patent Application Publication
(10) Pub. No.: US 2023/0119193 A1
(43) Pub. Date: Apr. 20, 2023

(54) HIGH-TEMPERATURE POWER MODULE INTEGRATED WITH AN OPTICALLY GALVANIC ISOLATED GATE DRIVER

(71) Applicant: Board of Trustees of the University of Arkansas, Little Rock, AR (US)

(72) Inventors: Zhong Chen, Fayetteville, AR (US); Alan Mantooth, Fayetteville, AR (US); Shui-qing Yu, Fayetteville, AR (US); David Gonzalez, Fayetteville, AR (US); Pengyu Lai, Fayetteville, AR (US); Syam Madhusoodhanan, Fayetteville, AR (US)

(21) Appl. No.: 17/968,387

(22) Filed: Oct. 18, 2022

Related U.S. Application Data
(60) Provisional application No. 63/257,030, filed on Oct. 18, 2021.

(51) Int. Cl. H03K 17/78

(52) U.S. Cl. CPC H03K 17/78

(57) ABSTRACT

A high-temperature power module integrated with an optically galvanic isolated gate driver. The power module includes one or more galvanic isolated gate driver boards, where each galvanic isolated gate driver board includes an optocoupler configured to transfer electrical signals between two isolated circuitry by using light. Furthermore, each galvanic isolated gate driver board includes a gate driver connected to the optocoupler, where the gate driver includes a power amplifier that receives a signal and produces a current drive input for a gate of a transistor.

### GOVERNMENT INTERESTS

This invention was made with government support under Grant Number EEC1449548 awarded by the National Science Foundation. The U.S. government has certain rights in the invention.

### TECHNICAL FIELD

The present invention relates generally to power modules, and more particularly to a high-temperature power module integrated with an optically galvanic isolated gate driver.

### BACKGROUND

A power module or power electronic module provides the physical containment for several power components, such as power semiconductor devices. These power semiconductors are typically soldered or sintered on a power electronic substrate that carries the power semiconductors, provides electrical and thermal contact and electrical insulation where needed.

Wide bandgap semiconductors, such as silicon carbide (SiC) or gallium nitride (GaN), are widely considered as the power semiconductor of choice due to their wide energy band-gap, high breakdown field strength, high operating junction temperature, high carrier saturation drift velocity, and high thermal conductivity.

Innovative research and development on wide bandgap materials, such as SiC and GaN, has helped overcome the design limitations in the field of power electronics by systematically replacing the conventional silicon technology. The superior material quality of wide bandgap-based devices allows a volumetrically-efficient power system design to achieve power modules with even higher efficiency and power density. Furthermore, the miniaturization trend in the high-temperature power module design is primarily driven by the integration of wide bandgap materials. Although the integration of these new material devices allows a compact module design, a bulky cooling system is still necessary to control the heat generated from the high current density at high frequencies. The self-heat generation of these power devices interferes with the signal stability and behavior of common passive components. If, however, switching efficiencies could be achieved, there would be less heat generated thereby reducing the need for a bulky cooling system as well as limiting the interference with the signal stability and behavior of the passive components.

### SUMMARY

In one embodiment of the present disclosure, a power module comprises one or more galvanic isolated gate driver boards, where each of the one or more galvanic isolated gate driver boards comprises an optocoupler configured to transfer electrical signals between two isolated circuitry by using light. Furthermore, each of the one or more galvanic isolated gate driver boards comprises a gate driver connected to the optocoupler, where the gate driver comprises an amplifier that receives a signal and produces a current drive input for a gate of a transistor.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present invention can be obtained when the following detailed description is considered in conjunction with the following drawings, in which:

FIG. 1 illustrates a three-dimensional model of a 1.2kV/120 A power module with galvanic isolated gate driver boards in accordance with an embodiment of the present invention;

FIG. 2 illustrates an exploded view of the three-dimensional model of the low temperature co-fired ceramic (LTCC)-based gate driver board in accordance with an embodiment of the present invention;

FIGS. 3A-3C are a schematic representation of the electrical measurement setup in accordance with an embodiment of the present invention;

FIG. 4 is a graph illustrating the high temperature optocoupler characterization and comparison with a commercial device in accordance with an embodiment of the present invention;

FIG. 5 is a schematic representation of the design of a gate driver in accordance with an embodiment of the present invention; and

FIGS. 6A-6B illustrate the simulation results from the designed gate driver circuit of the present invention in accordance with an embodiment of the present invention.

### DETAILED DESCRIPTION

As stated in the Background section, a power module or power electronic module provides the physical containment for several power components, such as power semiconductor devices. These power semiconductors are typically soldered or sintered on a power electronic substrate that carries the power semiconductors, provides electrical and thermal contact and electrical insulation where needed.

Wide bandgap semiconductors, such as silicon carbide (SiC) or gallium nitride (GaN), are widely considered as the power semiconductor of choice due to their wide energy band-gap, high breakdown field strength, high operating junction temperature, high carrier saturation drift velocity, and high thermal conductivity.

Innovative research and development on wide bandgap materials, such as SiC and GaN, has helped overcome the design limitations in the field of power electronics by systematically replacing the conventional silicon technology. The superior material quality of wide bandgap-based devices allows a volumetrically-efficient power system design to achieve modules with even higher efficiency and power density. Furthermore, the miniaturization trend in the high-temperature power module design is primarily driven by the integration of wide bandgap materials. Although the integration of these new material devices allows a compact module design, a bulky cooling system is still necessary to control the heat generated from the high current density at high frequencies. The self-heat generation of these power devices interferes with the signal stability and behavior of common passive components. If, however, switching efficiencies could be achieved, there would be less heat generated thereby reducing the need for a bulky cooling system as well as limiting the interference with the signal stability and behavior of the passive components.

The principles of the present invention provide the means for achieving higher switching efficiencies via the innovative approach in the gate driver circuity design and placement as discussed further below.

In one embodiment, the principles of the present invention are directed to an innovative design of a 250° C. continuous operation high temperature 1.2kV/120 A power module integrated with an optically galvanic isolated gate driver.

Wide bandgap based high-density power modules are widely used in size and weight-sensitive applications, such as space exploration and electric motor drives. By incorporating an optically galvanized gate driver in the power module design, the system's form factor is significantly reduced thereby leading to higher overall efficiency. By replacing a conventional magnetically isolated gate driver with optical components, the electromagnetic interference (EMI) immunity and electrostatic discharge (ESD) performance of the power module are greatly improved.

In one embodiment, a 1.2kV/120 A high-temperature power module integrated with an optically galvanic isolated gate driver is designed. In one embodiment, the power module consists of a 1.2kV/120 A switching module targeted to operate at a junction temperature of 250° C. In one embodiment, the power module includes a low temperature co-fired ceramic (LTCC)-based gate driver board that consists of passive components rated for 250° C. and above. In one embodiment, the galvanic isolation in the gate driver board is achieved by high-temperature optocouplers as discussed below. The inclusion of high-temperature passive components and the low form factor optocoupler enable an ever-higher power density design with low switching losses.

Furthermore, in one embodiment, the present invention provides optimized thermal management. Poor thermal management on high-density power modules is a latent challenge that limits the system's reliability and performance. In one embodiment, the designed packaging solutions for power modules were optimized for electrical and thermal performance using PowerSynth, COMSOL Multiphysics®, and ANSYS®. In one embodiment, the designed module consisted of six commercially available power devices—three in parallel per switching position. The parasitic power inductance of the designed module is 7.5 nH, and the junction to case thermal resistance is 0.125° C./W.

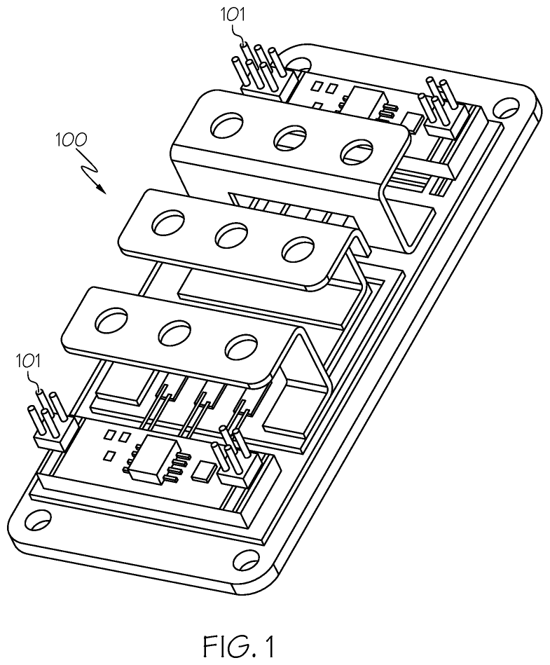

Referring now to the Figures in detail, FIG. 1 illustrates a three-dimensional model of a 1.2kV/120 A power module 100 with galvanic isolated gate driver boards 101 in accordance with an embodiment of the present invention. In one embodiment, LTCC galvanic isolated driver boards 101 are attached at each end of switching module 100 as shown in FIG. 1. Two LTCC boards 101 are designed—one for each side of module 100—in order to drive power module 100. In one embodiment, Aluminum Nitride (AlN) ceramic is used for the substrate material of module 100 in order to minimize reliability concerns due to the coefficient of thermal expansion (CTE) mismatch between LTCC-based gate driver boards 101 as well as to improve thermal performance. A reduced CTE mismatch enhances the reliability of the system during temperature swings. The multilayer LTCC fabrication process allows a fully embedded design of some passive components enabling a compact packaging design.

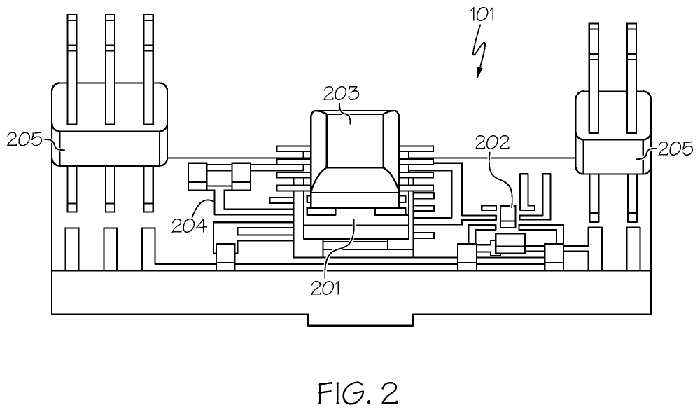

In one embodiment, LTCC-based gate driver board 101 houses commercially available high temperature passive and active components. An illustration of a schematic representation of gate driver board 101 is shown in FIG. 2.

FIG. 2 illustrates an exploded view of the three-dimensional model of LTCC-based gate driver board 101 (FIG. 1) in accordance with an embodiment of the present invention.

Referring to FIG. 2, LTCC-based gate driver board 101 includes an optocoupler 201 connected to a gate driver integrated circuit (IC) 202, a high temperature amplifier 203 and passive components 204. Furthermore, as illustrated in FIG. 2, LTCC-based gate driver board 101 includes input/output (I/O) pins 205. In one embodiment, optocoupler 201 is configured to transfer electrical signals between two isolated circuitry by using light.

In one embodiment, galvanic isolation is designed using optocoupler 201. In one embodiment, optocoupler 201 includes high-temperature light-emitting diodes (LEDs) and/or photodiodes. In one embodiment, the packaging of optical components was designed using LTCC technology. In one embodiment, multiple LTCC-based optocouplers 201 with different optical device combinations were characterized at high temperatures to understand the device behavior better. The high-temperature characterization of optocouplers 201 helps to identify changes in the current transfer ratio (CTR) and signal-to-noise ratio (SNR).

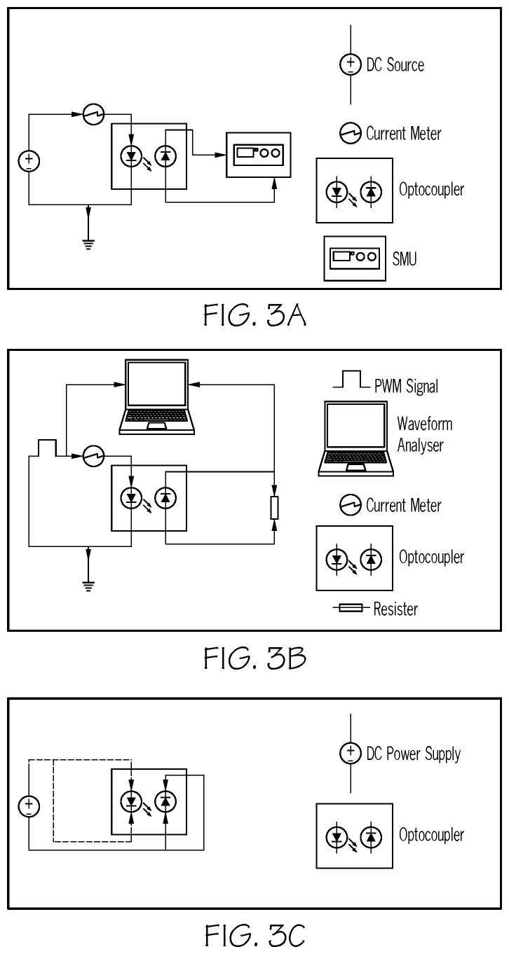

FIGS. 3A-3C are a schematic representation of the electrical measurement setup in accordance with an embodiment of the present invention. In particular, FIG. 3A is a schematic representation of current-voltage (IV) measurements. FIG. 3B is a schematic representation of transient measurements. FIG. 3C is a schematic representation of the blocking voltage measurement.

FIGS. 3A-3C illustrate the different test setups used for high-temperature analysis. The transient measurements (see FIG. 3B) enable an individual to study the input and output signal behaviors in detail. The temperature-dependent study on bandwidth, slew rate, and rise/fall times enable a highly efficient peripheral circuit design.

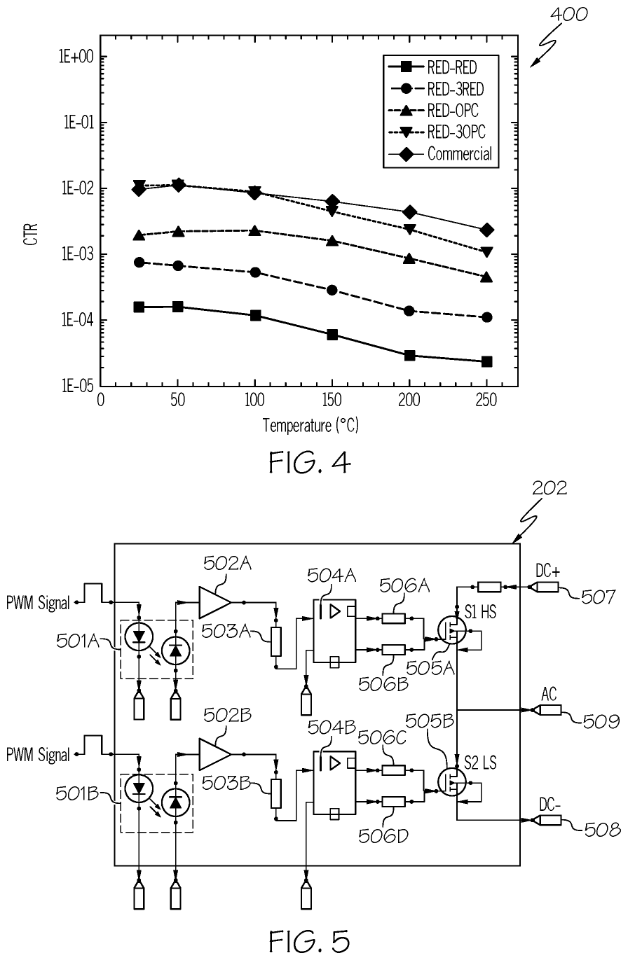

In one embodiment, optocoupler 201 consists of gallium nitride (GaN) based commercially available red LEDs as both the emitter and detector. The high-temperature characterization of the packaged optocoupler 201 is shown in FIG. 4.

FIG. 4 is a graph 400 illustrating the high temperature optocoupler characterization and comparison with a commercial device (e.g., IL300 by Vishay®), where “red” refers to the AlGaAs red LED and “OPC” refers to the AlGaN red LED commercial device, in accordance with an embodiment of the present invention. As shown in FIG. 4, the graph is of the current transfer ratio (CTR) versus temperature (in Celsius) for the high temperature optocoupler characterization and commercial device discussed above.

In one embodiment, the galvanic isolation circuitry consists of a high-temperature optocoupler, a transimpedance amplifier (TIA), and a gate driver stage. While the high-temperature optocoupler ensures the signal isolation, the TIA stage amplifies the signal and feeds it to the gate driver stage. FIG. 5 is a schematic representation of the design of gate driver integrated circuit 202 (FIG. 2) in accordance with an embodiment of the present invention.

Referring to FIG. 5, gate driver integrated circuit 202 (FIG. 2) includes a transimpedance amplifier 502A, 502B configured to receive as its input a PWM (pulse width modulated) signal transferred by optocoupler 501A, 501B (optocouplers 501A, 501B are equivalent to optocoupler 201), respectively, during the amplifier stage. An example of such a transimpedance amplifier 502A, 502B is OPA211 from Texas Instruments®. The output of transimpedance amplifier 502A, 502B is inputted (low-power input) via a resistor 503A, 503B, respectively, into the gate driver circuity (e.g. flip-flop) 504A, 504B, respectively, during the gate driver stage, which produces a high-current drive input for the gate of a high-power transistor (simply referred to herein as a “switch”) 505A, 505B, respectively. Examples of switches 505A, 505B include, but not limited to, insulated-gate bipolar transistor (IGBT), power metal-oxide-semiconductor field-effect transistor (MOSFET), etc. Switch 505A is identified as “S1 HS” and switch 505B is identified as “S2 LS” in FIG. 5. In one embodiment, the high-current drive input passes through resistors 506A-506D as shown in FIG. 5. Furthermore, FIG. 5 illustrates the direct current (DC)+ polarity 507 (electrode positive or “reverse”) inputted to switch 505A and DC-polarity 508 (electrode negative or “straight”) outputted from switch 505B. Furthermore, FIG. 5 illustrates the alternating current (AC) output 509.

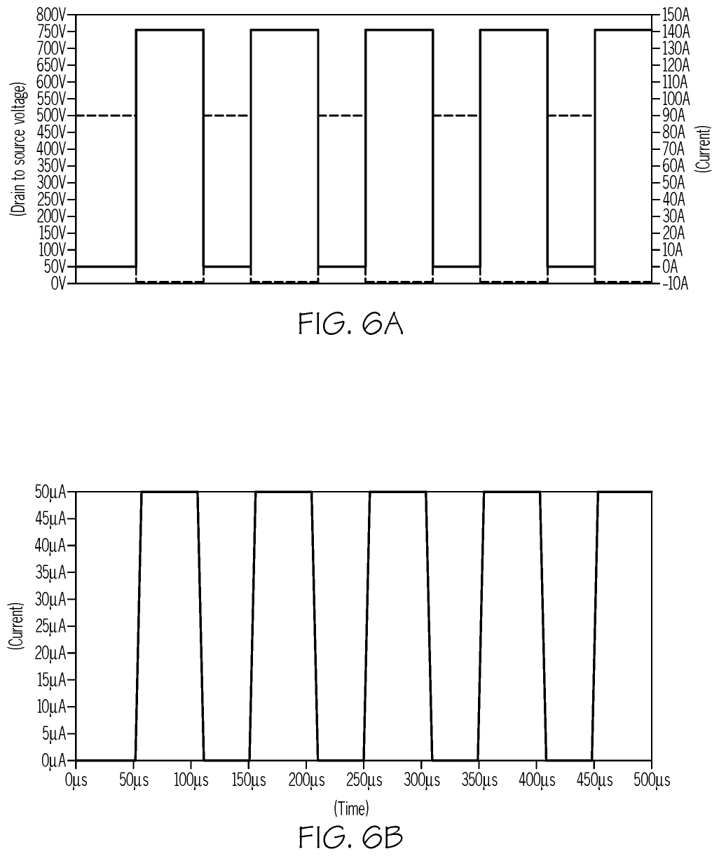

In one embodiment, the initial simulation results show that the designed circuitry of the present invention can drive the CPM2-1200-0025B power devices from Wolfspeed®, as shown in FIGS. 6A-6B. FIGS. 6A-6B illustrate the simulation results from the designed gate driver circuit of the present invention in accordance with an embodiment of the present invention. FIG. 6A illustrates the drain to source voltage versus current. FIG. 6B illustrates the LTCC-based optocoupler output.

As a result of the foregoing, there is signal stability at 250° C. due to the high-temperature optocoupler with the TIA stage.

Furthermore, the principles of the present invention improve the technology of power modules by utilizing a power module consisting of a 1.2kV/120 A switching module targeted to operate at a junction temperature of 250° C. The low temperature co-fired ceramic (LTCC)-based gate driver board consists of passive components rated 250° C. and above. The galvanic isolation in the gate driver board is achieved by high-temperature optocouplers. By replacing a conventional magnetically isolated gate driver with optical components, the electromagnetic interference (EMI) immunity and electrostatic discharge (ESD) performance of the power module are improved. The inclusion of high-temperature passive components and the low form factor optocoupler enables an ever-higher power density design with low switching losses.

The principles of the present invention achieve various advantages including, but not limited to, having a 500 times size reduction over conventional power module designs and achieving superior EMI and ESD performance over conventional power module designs.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A power module, comprising:
one or more galvanic isolated gate driver boards, wherein each of said one or more galvanic isolated gate driver boards comprises:
an optocoupler configured to transfer electrical signals between two isolated circuitry by using light; and
a gate driver connected to said optocoupler, wherein said gate driver comprises an amplifier that receives a signal and produces a current drive input for a gate of a transistor.

2. The power module as recited in claim 1, wherein each of said one or more galvanic isolated gate driver boards comprises:
an amplifier connected to said optocoupler.

3. The power module as recited in claim 1, wherein each of said one or more galvanic isolated gate driver boards comprises:
passive components connected to said optocoupler.

4. The power module as recited in claim 1, wherein each said one or more galvanic isolated gate driver boards comprises:
input/output pins.

5. The power module as recited in claim 1, wherein said optocoupler is configured to ensure signal isolation.

6. The power module as recited in claim 1, wherein said transistor comprises one of the following: an insulated-gate bipolar transistor (IGBT) and a metal-oxide-semiconductor field-effect transistor (MOSFET).

7. The power module as recited in claim 1, wherein said optocoupler comprises one or more of the following: a light-emitting diode and a photodiode.

8. The power module as recited in claim 1, wherein said amplifier corresponds to a transimpedance amplifier.

9. The power module as recited in claim 8, wherein said transimpedance amplifier amplifies said signal and feeds it to a gate driver stage.

10. The power module as recited in claim 1, wherein said gate driver comprises:
a first transimpedance amplifier and a second transimpedance amplifier.

11. The power module as recited in claim 10, wherein each of said first and second transimpedance amplifiers is configured to receive a pulse width modulated signal.

12. The power module as recited in claim 11, wherein said pulse width modulated signal is transferred by a first optocoupler and a second optocoupler.

13. The power module as recited in claim 11, wherein said gate driver further comprises:
a first circuitry and a second circuitry for producing said current drive input for a first gate of a first transistor and a second gate of a second transistor, respectively, wherein an output of said first transimpedance amplifier and said second transimpedance amplifier is inputted into said first circuitry and said second circuity, respectively.

14. The power module as recited in claim 13, wherein said output of said first transimpedance amplifier and said second transimpedance amplifier is inputted into said first circuitry and said second circuitry, respectively, during a gate driver stage.

15. The power module as recited in claim 13, wherein each of said first circuitry and said second circuitry comprises a flip-flip.

16. The power module as recited in claim 13, wherein said current drive input is passed through resistors.

17. The power module as recited in claim 13, wherein an output of said gate driver comprises a direct current positive polarity output, a direct current negative polarity output and an alternating current output.

18. The power module as recited in claim 17, wherein said direct current positive polarity output is inputted to said first transistor.

19. The power module as recited in claim 18, wherein said direct current negative polarity output is outputted from said second transistor.

20. The power module as recited in claim 1, wherein said optocoupler comprises gallium nitride.
